(19) United States
(12) Patent Application Publication
(10) Pub. No.: US 2006/0017093 A1
(43) Pub. Date: Jan. 26, 2006

(54) Semiconductor devices with overlapping gate electrodes and methods of fabricating the same

(76) Inventors: Sung-Un Kwon, Gyeonggi-do (KR); Jae-Seung Hwang, Gyeonggi-do (KR)

Correspondence Address: MYERS BIGEL SIBLEY & SAJOVEC, PO BOX 37428, RALEIGH, NC, 27627, US

(21) Appl. No.: 11/156,914

(22) Filed: Jun. 20, 2005

(30) Foreign Application Priority Data
Jul. 21, 2004 (KR) 2004-56856

(51) Int. Cl. H01L 29/788

(52) U.S. Cl. 257/315; 257/316; 257/317; 257/321

(57) ABSTRACT

A semiconductor device, such as a flash memory device, includes an isolation region provided in a trench in a substrate and having a recess therein. The device also includes a tunnel oxide layer pattern on the substrate adjacent the isolation region, and a first gate electrode provided on the tunnel oxide layer pattern and extending onto a portion of the isolation region adjacent the recess. The device further includes a dielectric layer provided on the first gate electrode and a second gate electrode provided on the dielectric layer and extending into the recess in the isolation region. The first gate electrode may include a conductive layer pattern provided on the tunnel oxide layer pattern and a conductive spacer provided on a sidewall of the first conductive layer pattern adjacent the recess in the isolation region.

### CROSS REFERENCE TO RELATED APPLICATION

This application claims priority under 35 USC § 119 to Korean Patent Application No. 2004-56856 filed on Jul. 21, 2004, the disclosure of which is herein incorporated by reference in its entirety.

### BACKGROUND OF THE INVENTION

The present invention relates to semiconductor devices and fabrication methods therefor and, more particularly, to gate electrode structures for semiconductor devices, such as nonvolatile memory devices, and fabrication methods therefor.

In a conventional method of manufacturing a flash memory device, after a trench is formed at a surface portion of a substrate, an oxide layer and a polysilicon layer are sequentially formed on an active region of the substrate. The oxide layer and the polysilicon layer are partially etched to form a tunnel oxide layer pattern and a floating gate on the substrate. Thereafter, a dielectric layer and a control gate are successively formed on the floating gate.

However, alignment errors may frequently occur in a photolithography process used in forming the tunnel oxide layer pattern and the floating gate. Particularly, when the flash memory device includes a minute pattern having a width of below about 70 nm, alignment errors may more frequently occur. Consequently, the active region of the substrate may be damaged in subsequent processes for forming the dielectric layer and the control gate.

Recently, a self-aligned process has been developed for forming a flash memory device that may reduce the above-mentioned alignment errors by simultaneously defining a field region and an active region of a substrate. In particular, after a pad oxide layer and a hard mask layer are sequentially formed on the substrate, the pad oxide layer and the hard mask layer are etched to form a pad oxide layer pattern and a hard mask layer pattern on the substrate. In this etching process, the substrate may be partially etched to form a trench therein. Hence, the active region and the field region are simultaneously defined. An insulation layer is formed, filling the trench. The insulation layer is removed until the hard mask layer pattern is exposed, thereby forming an isolation region in the trench. A tunnel oxide layer is formed on a portion of the substrate exposed by the isolation region. After a polysilicon layer is formed on the tunnel oxide layer and the isolation region, the polysilicon layer is partially etched to form a floating gate over the substrate. A dielectric layer and a control gate are sequentially formed on the floating gate.

In the above-mentioned self-aligned process, a portion of the tunnel oxide layer at a boundary between the active region and the isolation region may be thin. In addition, a void may be generated in the polysilicon layer because a process margin thereof may be insufficient to completely fill up a gap between the pad oxide layer pattern and the hard mask layer pattern.

A method of manufacturing a flash memory device by employing two polysilicon layers for a floating gate is disclosed Korean Laid-Open Patent Publication No. 2003-94443 or U.S. Pat. No. 6,620,681. In particular, after a tunnel oxide layer, a first polysilicon layer and a hard mask layer are sequentially formed on a substrate, the tunnel oxide layer, the first polysilicon layer and the hard mask layer are etched to thereby form a hard mask layer pattern, a first polysilicon layer pattern and a tunnel oxide layer pattern on the substrate. In the etching process, a portion of the substrate exposed by these patterns is partially removed to form a trench thereon so that an active region and a field region are simultaneously defined. An insulation layer is formed on the substrate to fill the trench. The insulation layer is partially removed until the hard mask layer pattern is exposed. After the hard mask layer pattern is removed, a second polysilicon layer is formed on the first polysilicon layer. The second polysilicon layer is etched until the insulation layer is exposed to thereby form a second polysilicon layer pattern. The insulation layer is partially removed so that an isolation region is formed in the trench. Thus, a floating gate including the first and the second polysilicon layer patterns is formed on the active region. A dielectric layer and a control gate are sequentially formed on the floating gate. Such a method for forming the floating gate including two polysilicon layer patterns is relatively complex, so that the time and/or cost of the manufacturing process may be undesirably great.

### SUMMARY OF THE INVENTION

In some embodiments of the present invention, a semiconductor device, such as a flash memory device, includes an isolation region provided in a trench in a substrate and having a recess therein. The device also includes a tunnel oxide layer pattern on the substrate adjacent the isolation region, and a first gate electrode provided on the tunnel oxide layer pattern and extending onto a portion of the isolation region adjacent the recess. The device further includes a dielectric layer provided on the first gate electrode and a second gate electrode provided on the dielectric layer and extending into the recess in the isolation region. The first gate electrode may include a conductive layer pattern provided on the tunnel oxide layer pattern and a conductive spacer provided on a sidewall of the first conductive layer pattern adjacent the recess in the isolation region.

In some embodiments, the tunnel oxide layer pattern may have a thickness of about 10 Å to about 500 Å. The conductive layer pattern may have a thickness of about 700 to about 1,500 Å. The recess may have a depth of about 200 Å to about 300 Å.

Each of the conductive layer, the conductive spacer and the second gate electrode include doped polysilicon. The dielectric layer may include an oxide-nitride-oxide film or a metal oxide film.

In some method embodiments of the present invention, a tunnel oxide layer is formed on a substrate and a conductive layer is formed on the tunnel oxide layer. Portions of the conductive layer, the tunnel oxide layer, and the substrate are removed to form a pattern structure including a tunnel oxide layer pattern and a conductive layer pattern on the substrate and a trench in the substrate adjacent the pattern structure. An isolation region is formed in the trench, and a conductive spacer is formed on a sidewall of the first conductive layer pattern and on the isolation region to form a first gate electrode including the conductive layer pattern and the conductive spacer. A recess is formed in the isolation region adjacent the spacer, a dielectric layer is formed on the first gate electrode, and a second gate electrode is formed on the dielectric layer, extending into the recess in the isolation region.

Forming a tunnel oxide layer may include thermally oxidizing the substrate to produce a tunnel oxide layer having a thickness of about 10 Å to about 500 Å. Forming a conductive layer may include forming the conductive layer by a thermal decomposition process to produce a conductive layer having a thickness of about 700 Å to about 1,500 Å.

Each of the conductive layer, the spacer and the second gate electrode may be formed using a thermal decomposition process followed by an impurity doping process. The thermal decomposition process may be performed at a temperature of about 500° C. to about 650° C. and a pressure of about 25 Pa to about 150 Pa. The thermal decomposition process may be performed using a pure silane gas or a silane gas diluted with nitrogen, wherein the diluted silane gas includes about 20 weight percent to about 30 weight percent of silane.

In further embodiments, forming a conductive layer includes forming a first conductive layer. Removing portions of the conductive layer, the tunnel oxide layer, and the substrate to form a pattern structure including a tunnel oxide layer pattern and a conductive layer pattern on the substrate and a trench in the substrate adjacent the pattern structure is preceded by forming a hard mask layer on the first conductive layer. Removing portions of the conductive layer, the tunnel oxide layer, and the substrate to form a pattern structure including a tunnel oxide layer pattern and a conductive layer pattern on the substrate and a trench in the substrate adjacent the pattern structure includes removing portions of the hard mask layer, the conductive layer, the tunnel oxide layer and the substrate to form a pattern structure including a hard mask layer pattern on the tunnel oxide layer pattern and the conductive layer pattern. Forming a conductive spacer includes forming a second conductive layer on the pattern structure and the isolation region, and etching with an etchant having an etching selectivity between the hard mask layer pattern and the second conductive layer to form the conductive spacer. Forming a recess in the isolation region adjacent the spacer may include etching with an etchant having an etching selectivity between the isolation region and the hard mask layer pattern. The recess may have a depth of about 200 Å to about 300 Å.

In still further embodiments, a tunnel oxide layer is formed on a substrate, and a polysilicon film is formed on the tunnel oxide layer. Portions of the tunnel oxide layer and the polysilicon film are removed to form a pattern structure including a tunnel oxide layer pattern and a polysilicon film pattern on the substrate. A trench is formed in the substrate adjacent the pattern structure, and an isolation region is formed in the trench. A polysilicon spacer is formed on a sidewall of the first polysilicon layer pattern to form a first polysilicon gate electrode including the first polysilicon layer pattern and the polysilicon spacer. A recess is formed in the isolation region adjacent the polysilicon spacer. A dielectric layer is formed on the first polysilicon gate electrode and the isolation region, and a second polysilicon gate electrode is formed on the dielectric layer and extending into the recess.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional view illustrating a semiconductor device in accordance with some exemplary embodiments of the present invention; and

FIGS. 2 to 9 are cross-sectional views illustrating operations for manufacturing a semiconductor device in accordance with further exemplary embodiments of the present invention.

### DETAILED DESCRIPTION OF EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a semiconductor device in accordance with some exemplary embodiments of the present invention. Referring to FIG. 1, a trench 11 is formed in a substrate 10. The substrate 10 may include a silicon wafer or a silicon-on-insulator (SOI) substrate. Because the trench 11 is positioned at the surface portion of the substrate 10, an isolation region 12 may be formed in the trench 11 by an isolation region fabrication process, such as a shallow trench isolation (STI) process. The isolation region 12 may be an oxide formed from a deposition process, such as a high-density plasma chemical vapor deposition (HDP-CVD) oxide, which fills the trench 11.

The isolation region 12 includes an upper portion 12a having a recess therein. In particular, a center of the upper portion 12a of the isolation region 12 is recessed to a predetermined depth. As appreciated by the present inventors, when the recess formed at the upper portion 12a of the isolation region 12a has a depth less than about 200 Å, interference between adjacent floating gates may not be sufficiently limited. As appreciated by the present inventors, when the recess formed at the upper portion 12a of the isolation region 12 has a depth greater than about 300 Å, a failure may occur in forming the recess at the upper portion 12a of the isolation region 12. Therefore, it may be advantageous that the recess formed at the upper portion 12a of the isolation region 12 has a depth of about 200 Åto about 300 Å.

A tunnel oxide layer pattern 14 is formed on portion of the substrate 10 between the isolation regions 12. The tunnel oxide layer pattern 14 is positioned in an active region of the substrate 10. For example, the tunnel oxide layer pattern 14 may include an oxide, such as silicon oxide. The tunnel oxide layer pattern 14 may be formed on the exposed portion of the substrate 10 by partially etching a tunnel oxide layer after the tunnel oxide layer is formed on the substrate 10. The tunnel oxide layer may be formed on the substrate 10 by, for example, a thermal oxidation process or a radical oxidation process. The tunnel oxide layer pattern 14 may have a thickness of about 10 Å to about 500 Å. For example, the tunnel oxide layer pattern 14 may have a thickness of about 50 Åto about 300 Å. In some embodiments, the thickness of the tunnel oxide layer pattern 14 is in a range of about 50 Å to about 200 Å. In further embodiments, the tunnel oxide layer pattern 14 may have a thickness of about 100 Å.

A first conductive layer pattern 16 is formed on the tunnel oxide layer pattern 14. The first conductive layer pattern 16 may include, for example, doped polysilicon. Alternatively, the first conductive layer pattern 16 may include a metal or a metal nitride. Examples of metals and metal nitrides that can be used for the first conductive layer pattern 16 include tungsten (W), titanium (Ti), tantalum (Ta), aluminum (Al), platinum (Pt), copper (Cu), tungsten nitride (WN), titanium nitride (TiN), and tantalum nitride (TaN). These can be used alone or in combination. The first conductive layer pattern 16 is formed on the tunnel oxide layer pattern 14 by patterning a conductive layer formed on the substrate 10 by a thermal decomposition process.

In some exemplary embodiments of the present invention, the first conductive layer may be formed on the substrate 10 using two operations. In a first operation, a polysilicon film is formed on the substrate 10. Impurities are doped into the polysilicon film in a second operation. When the polysilicon film is formed by a plasma enhanced chemical vapor deposition process, the film may not have desirable electrical characteristics. Accordingly, the polysilicon film may be formed on the substrate 10 by a thermal decomposition process such that the first conductive layer pattern 16 has desired electrical characteristics.

In the thermal decomposition process, a gas including silane (SiH₄) may be thermally decomposed in a furnace where the substrate 10 is loaded, thereby forming the polysilicon film on the substrate 10. The gas for forming the first polysilicon film may include a pure silane gas or a diluted silane gas with nitrogen. The diluted silane gas may include about 20 to about 30 weight percent of silane. When the polysilicon film is formed at a temperature of below about 500° C. in the first operation, a formation rate of the first polysilicon film may be relatively slow. When the polysilicon film is formed at a temperature of above about 650° C., the gas including silane may be rapidly consumed in the first operation so that a uniformity of the first polysilicon film may be degraded. Therefore, it may be advantageous to form the polysilicon film at a temperature of about 500 to about 650° C. in the first operation. In addition, the formation rate of the polysilicon film may be accelerated under a pressure of about 25 to about 150 Pa when the polysilicon film is formed at the temperature of about 500 to about 650° C.

The second operation of doping the impurities into the polysilicon film may include a diffusion process, an ion implantation process or an in-situ doping process. The impurities may include, for example, phosphorus (P), arsenic (As), boron (B) or indium (In). For example, phosphorus ions may be doped into the polysilicon film when a first gate electrode 18 including the first conductive layer pattern 16 has a P-type. Boron ions may be doped into the polysilicon film when the first gate electrode 18, including the first conductive layer pattern 16, has an N-type.

In further exemplary embodiments of the present invention, the first conductive layer pattern 16 of the first gate electrode 18 may have a single thin film structure. Thus, the first conductive layer pattern 16 may be efficiently formed without considering a gap-filling margin thereof. In some such embodiments, the first conductive layer pattern 16 may have a thickness of about 700 to about 1,500 Å. In some embodiments, the thickness of the first conductive layer pattern 16 may be in a range of about 800 Å to about 1,500 Å. In further embodiments, the first conductive layer pattern 16 may have a thickness of about 800 Å to about 1,200 Å. In still further embodiments, the first conductive layer pattern 16 may have a thickness of about 1,000 Å. Because the thickness of the first conductive layer pattern 16 may decrease in subsequent processes, the first conductive layer pattern 16 may be formed to a sufficient initial thickness to ensure a desired final thickness after execution of the subsequent processes.

A spacer 17 is formed on a sidewall of the first conductive layer pattern 16. Thus, the first gate electrode 18 includes the first conductive layer pattern 16 and the spacer 17. The spacer 17 may include a conductive material substantially identical to the conductive material of the first conductive layer pattern 16, that is, the spacer 17 may include doped polysilicon, a metal or a metal nitride. Examples of the metal or metal nitride that can be used for the spacer 17 include tungsten, titanium, tantalum, aluminum, platinum, copper, tungsten nitride, titanium nitride, and tantalum nitride. These can be used alone or in combination.

In some exemplary embodiment of the present invention, the spacer 17 is formed by partially etching a polysilicon film formed over the substrate 10 to cover the first conductive layer pattern 16 and the isolation region 12. The polysilicon film may be formed over the substrate 10 by a thermal decomposition process. The spacer 17 may be formed through two operations substantially identical to those used in producing the first conductive layer pattern 16 as described above. The spacer 17 is positioned on the upper portion 12a of the isolation region 12 except where a recess is to be formed, which is left exposed by the spacer 17. Therefore, the spacer 17 may serve as an etching mask for forming the recess at the upper portion 12a of the isolation region 12 by partially etching the isolation region 12. When the first conductive layer pattern 16 includes a metal or a metal nitride instead of doped polysilicon, the spacer 17 may also include the same metal or metal nitride, i.e., the first conductive layer pattern 16 and the spacer 17 may include the same material.

A dielectric layer 20 is formed on the first conductive layer pattern 16 and the isolation region 12, in particular, on the first conductive layer pattern 16, the spacer 17 and the recess of the isolation region 12. The dielectric layer 20 conforms to sidewall and bottom faces of the recess in the isolation region 12. The dielectric layer 20 may include an oxide-nitride-oxide film or a metal oxide film. Because the dielectric layer 20 covers the recess formed at the upper portion 12a of the isolation region 12, the dielectric layer 20 may have a surface area larger than that of a conventional dielectric layer. Therefore, a coupling constant of the dielectric layer 20 when used in a non-volatile memory device, such as a flash memory device, may increase.

A second gate electrode 22 is formed on the dielectric layer 22, filling the recess in the isolation region 12. The second gate electrode 22 also fills a gap between the first gate electrodes 18. The second gate electrode 22 may include a conductive material substantially identical to a conductive material used for the first conductive layer pattern 16, i.e., the second gate electrode 22 may include doped polysilicon, a metal or a metal nitride. For example, the second gate electrode 22 may include doped polysilicon formed by a thermal decomposition process. The second gate electrode 22 may be formed through two operations substantially identical to those for forming the first conductive layer pattern 16. When the first conductive layer pattern 16 includes a metal or a metal nitride instead of doped polysilicon, the second gate electrode 22 may also includes the metal or the metal nitride, i.e., the first conductive layer pattern 16 and the second gate electrode 22 may include substantially the same material.

In some exemplary embodiments of the present invention, the semiconductor device includes the first gate electrode 18, the dielectric layer 20 and the second gate electrode 22. When the first and the second gate electrodes 18 and 22 correspond to a floating gate and a control gate, respectively, the semiconductor device thus corresponds to the flash memory device. In this flash memory device, the dielectric layer 20 has relatively large surface area and the electron interference between the floating gates may be reduced because the floating gate includes the spacer 17 and the isolation region 12 includes the recess. In addition, because the first conductive layer pattern 16 of the floating gate has a single thin film structure, the first conductive layer pattern 16 may be easily formed without generating a void therein and considering a gap-filling margin thereof. Furthermore, an area of a cell region of the flash memory device may efficiently increase because the floating gate includes the spacer. As a result, the flash memory device may have improved electrical characteristics.

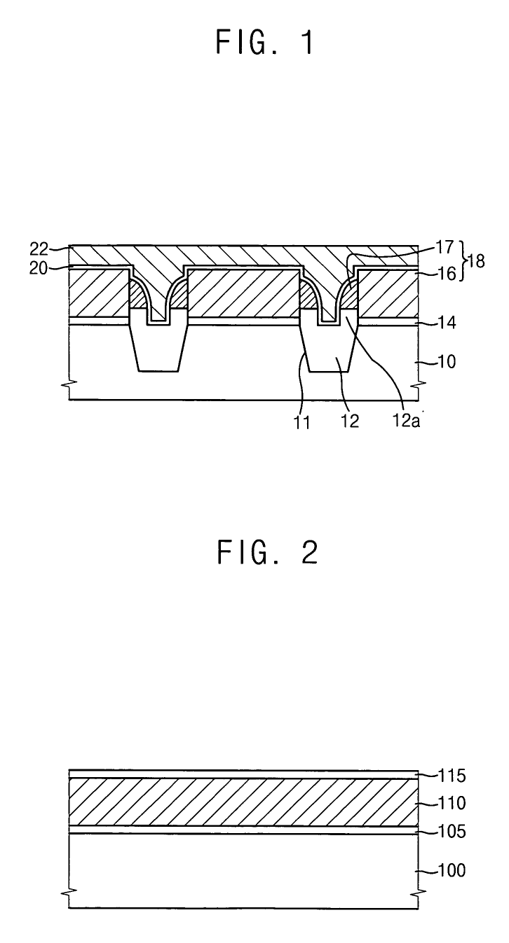

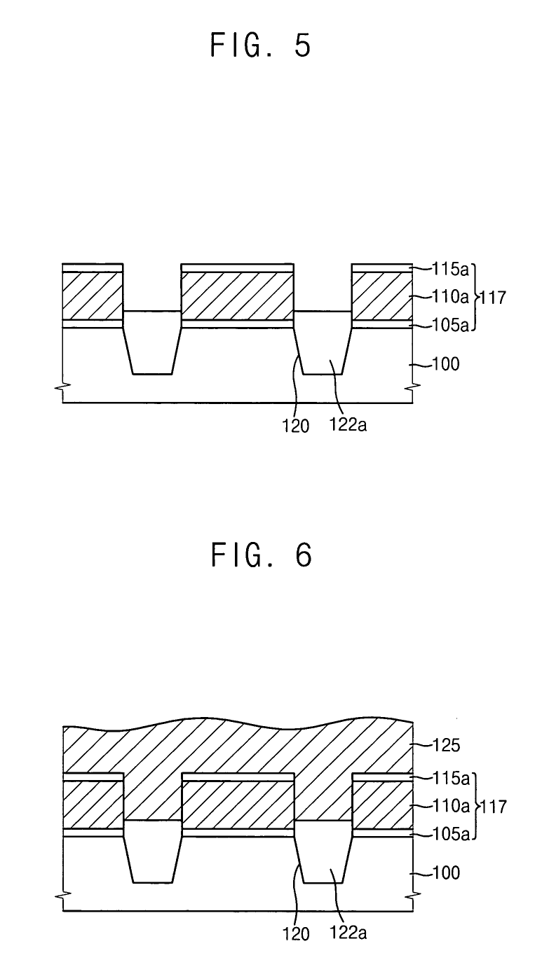

FIGS. 2 to 9 are cross-sectional views illustrating operations for manufacturing a semiconductor device in accordance with some exemplary embodiments of the present invention. Referring to FIG. 2, a tunnel oxide layer 105 is formed on a semiconductor substrate 100, such as a silicon substrate or an SOI substrate. The tunnel oxide layer 105 covers the entire surface of the substrate 100. The tunnel oxide layer 105 may be formed using an oxide, such as silicon oxide. The tunnel oxide layer 105 may be formed on the substrate 100 by a thermal oxidation process to have a thickness of about 100 Å. Because the tunnel oxide layer 105 is uniformly formed on the substrate 100 before forming an isolation region 122a (see FIG. 5), the tunnel oxide layer 105 may have a sufficient thickness at a boundary between the isolation region 122 and an active region of the substrate 100 without thinning of the tunnel oxide layer 105.

A first conductive layer 110, e.g., a polysilicon film, a metal film or a metal nitride film, is formed on the tunnel oxide layer 105. For example, the first conductive layer 110 may include a tungsten film, a titanium film, a tantalum film, an aluminum film, a platinum film, a copper film, a tungsten nitride film, a titanium nitride film, or a tantalum nitride film. These can be used alone or in combination.

A first conductive layer 110 formed from polysilicon may have a thickness of about 1,200 Å. Because about 200 Å of a first conductive layer 110 formed from polysilicon film may be consumed in successive etching processes, the first conductive layer 110 may be formed to have an initial thickness of greater than about 1,000 Å, e.g., an initial thickness of about 1,200 Å. When the first conductive layer 110 has an initial thickness of about 1,200 Å, the first conductive layer 110 may have a thickness of about 1,000 Å after the successive etching processes.

In a formation of the first conductive layer 110 from a polysilicon film, the first conductive layer 110 may be formed on the tunnel oxide layer 105 using two operations. A polysilicon film is formed on the tunnel oxide layer 105 in a first operation, and then impurities are doped into the first polysilicon layer in a second operation. The first operation may be carried out using a thermal decomposition process. In the first operation, a pure silane gas may be thermally decomposed to form a polysilicon film over the substrate 100 in a furnace at a temperature of about 500 to about 650° C. Alternatively, a diluted silane gas with nitrogen including about 20 to about 30 weight percent of silane may be thermally decomposed to form the polysilicon film on the tunnel oxide layer 105 in a furnace at a temperature of about 500 to about 650° C. In addition, the furnace where the substrate 100 is loaded may have a pressure of about 25 Pa to about 150 Pa.

The second operation may be performed using an ion implantation process. Because the ion implantation process may be performed at a substantially low temperature, the ion implantation process may be advantageously executed after the thermal decomposition process. Alternatively, the second operation may be carried out using a diffusion process or an in-situ doping process that dopes impurities into the polysilicon film.

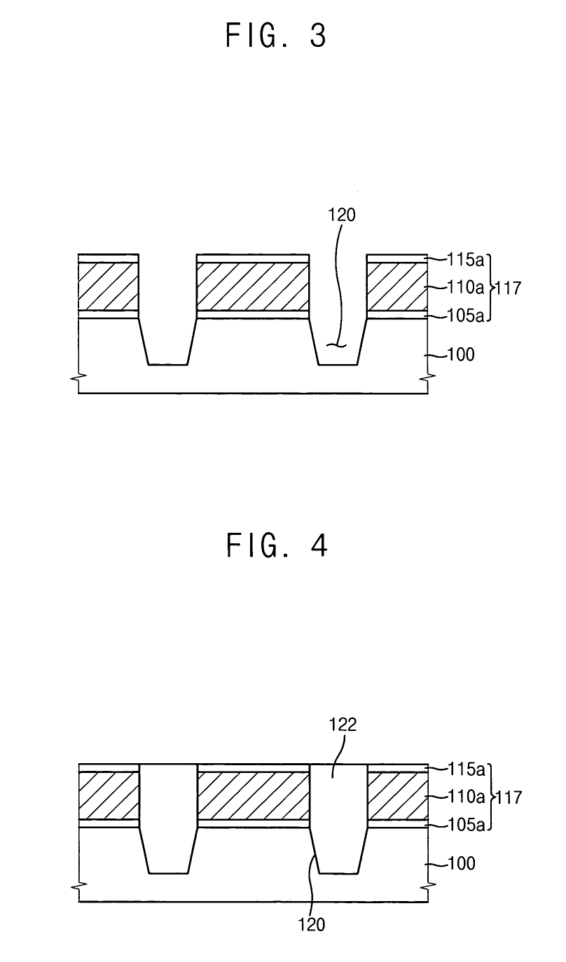

In some exemplary embodiments of the present invention, a first conductive layer 110 including a first polysilicon film may have a single thin film structure with a thickness of about 1,200 Å. The first conductive layer 110 may be patterned to thereby form a first conductive layer pattern 110a (see FIG. 3). If the first conductive layer 110 has a single thin film structure, the first conductive layer 110 may be formed on the tunnel oxide layer 105 without considering a gap-filling margin thereof. Additionally, the first conductive layer 110 may have a dense structure without generation of a void therein.

Referring now to FIG. 2, a hard mask layer 115 is formed on the first conductive layer 110. The hard mask layer 115 serves as an etching mask in a successive etching process for forming a trench 120 (see FIG. 3) in a surface of the substrate 100. The hard mask layer 115 may be formed using a nitride, such as silicon nitride, or an oxide, such as medium temperature oxide (MTO). Alternatively, the hard mask layer 115 may have a multi-layer structure in which a silicon nitride film and a MTO film are sequentially formed on the first conductive layer 110.

In some exemplary embodiments of the present invention, an antireflective layer (ARL) may be formed on the hard mask layer 115 to ensure a process margin in a subsequent photolithography process. The ARL may be formed from an oxynitride, such as silicon oxynitride.

Referring to FIG. 3, the hard mask layer 115, the first conductive layer 110, and the tunnel oxide layer 105 are partially etched to thereby form a pattern structure 117 on the substrate 100. The pattern structure 117 includes a tunnel oxide layer pattern 105a, a first conductive layer pattern 110a and a hard mask layer pattern 115a. The first conductive layer pattern 110a may include a polysilicon film pattern. The pattern structure 117 exposes a portion of the substrate 100. In some exemplary embodiments of the present invention, the hard mask layer pattern 115a may include a silicon nitride film pattern and a MTO film pattern.

In a formation of the pattern structure 117, the tunnel oxide layer pattern 105a, the first conductive layer pattern 110a and the hard mask layer pattern 115a are formed using a photolithography process. In the photolithography process, the hard mask layer 115, the first conductive layer 110, the tunnel oxide layer 105 are partially etched using a photoresist pattern as an etching mask after the photoresist pattern is formed on the hard mask layer 115. The photoresist pattern may be removed from the pattern structure 117 by an ashing process and/or a stripping process after the formation of the pattern structure 117.

Using the pattern structure 117 as an etching mask, the exposed portion of the substrate 100 is partially etched, thereby forming the trench 120 at the exposed portion of the substrate 100. When the trench 120 is formed, a portion of the substrate 100 covered with the pattern structure 117 is simultaneously defined as the active region. The trench 120 is, therefore, self-aligned relative to the pattern structure 117, i.e., the trench 120 is formed by a self-alignment process because the exposed portion of the substrate 100 is etched after the pattern structure 117 is formed. Hence, a process margin of the process for forming the trench 120 may be sufficiently ensured.

In certain exemplary embodiments of the present invention, the photoresist pattern used in the formation of the pattern structure 117 may be employed as an etching mask for forming the trench 120. When the photoresist pattern is used as the etching mask, the photoresist pattern is removed from the pattern structure 117 after the trench 120 is formed.

In other exemplary embodiments of the present invention, a sidewall of the trench 120 may be oxidized to cure damage to the trench 120 generated in the etching process. In particular, a sidewall oxide film may be formed on the sidewall of the trench 120 so that the damage to the trench 120 may be cured.

Referring to FIG. 4, after an insulation layer is formed on the pattern structure 117 to fill the trench 120, an upper portion of the insulation layer is removed until the pattern structure 117 is exposed, thus forming a trench structure 122 filling the trench 120. The insulation layer may be partially removed by a chemical mechanical polishing (CMP) process, an etch back process or a combination of CMP and etch back processes. The trench structure 122 also fills a gap between the pattern structures 117. The trench structure 122 may be formed using an insulation material, such as an oxide. For example, the trench structure 122 may include an oxide formed using a high-density plasma chemical vapor deposition process (HDP-CVD). An HDP-CVD oxide may have good flowability, so that the trench structure 122 may completely fill the trench 120 and the gap between the pattern structures 117.

Referring to FIG. 5, the trench structure 122 is partially removed by an etching process to form the isolation region 122a in the trench 120. The isolation region 122a has a height slightly greater than a depth of the trench 120. In the etching process for forming the isolation region 122a, an etching solution having an etching selectivity between the trench structure 122 and the hard mask layer pattern 115a may be used so that an upper portion of the trench structure 122 is removed without significant etching of the hard mask layer pattern 115a. For example, an etching solution including hydrogen fluoride may be employed for selectively etching the trench structure 122 when the hard mask layer pattern 115a includes silicon nitride and the trench structure 122 is made of the HDP-CVD oxide.

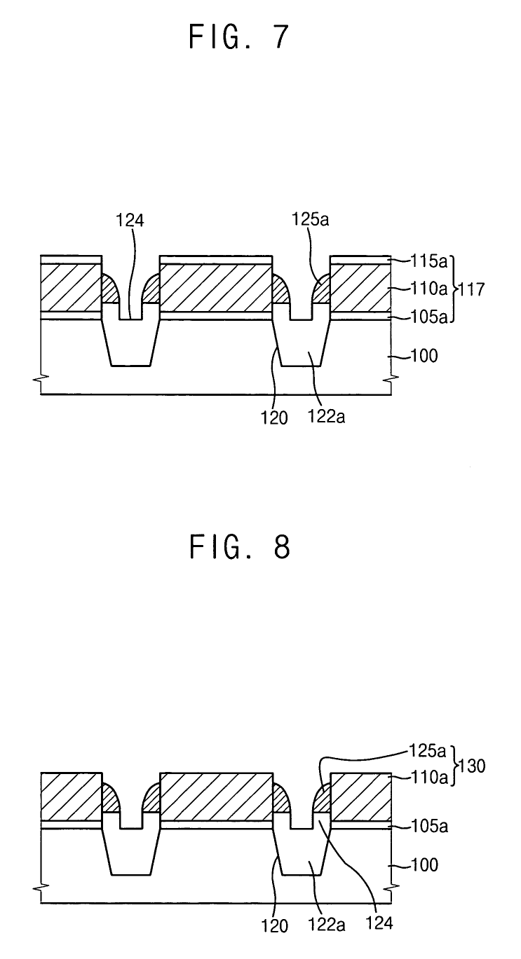

When an upper face of the isolation region 122a is substantially lower than that of the tunnel oxide layer pattern 105a, the active region may be damaged in subsequent etching processes for forming a recess 124 and/or a spacer 125a (see FIG. 7). The isolation region 122a may be formed to have an upper face substantially higher than or at least equal to that of the tunnel oxide layer pattern 105a by precisely controlling an etching rate of the trench structure 122.

Referring to FIG. 6, a second conductive layer 125 may include a polysilicon film is formed on the pattern structure 117 and the isolation region 122a. The second conductive layer 125 may be formed by a process substantially identical to the process for forming the first conductive layer 110, except for a thickness thereof. In particular, the second conductive layer 125 may be formed using two operations as described above. When the first conductive layer 110 includes a metal film or a metal nitride film, the second conductive layer 125 may also include a metal film or a metal nitride film. That is, the first and the second conductive layers 110 and 125 may include substantially the same material.

Referring to FIG. 7, the second conductive layer 125 may be partially removed by an anisotropic etching process, thereby forming the spacer 125a on a sidewall of the pattern structure 117. The second conductive layer 125 may be anisotropically etched using an etching gas or an etching solution that has an etching selectivity between the second conductive layer 125 and the hard mask layer pattern 115a. The spacer 125a corresponds to a remaining portion of the second conductive layer 125. The spacer 125a has a height substantially lower than that of the pattern structure 117. When the spacer 125a is formed on the sidewall of the pattern structure 117, an upper portion of the isolation region 122a is exposed.

The exposed upper portion of the isolation region 122a is partially etched to form a recess 124. In particular, the exposed upper portion of the isolation region 122a is partially etched using an etching solution that has an etching selectivity between the isolation region 122a and the hard mask layer pattern 115a. Thus, the recess 124 is formed at the exposed upper portion of the isolation region 122a. When the recess has a depth greater than about 300 Å, the hard mask layer pattern 115a may not sufficiently protect the isolation region 122a in the etching process for forming the recess 124. When the recess 124 has a depth less than about 200 Å, electron interference between floating gates may not be effectively limited. To avoid these problems, the recess 124 of the isolation region 122a may have a depth of about 200 to about 300 Å by adjusting an etching rate of the isolation region 122a.

In further exemplary embodiments of the present invention, the recess 124 may be formed at the upper portion of the isolation region 122a. Particularly, the hard mask layer pattern 115a is removed after the spacer 125a is formed. A photoresist pattern is formed at a position on the first conductive layer pattern 110a where the hard mask layer pattern 115a is placed. Subsequently, the upper portion of the isolation region 122a is partially etched using the photoresist pattern as an etching mask, thereby forming the recess 124 at the upper potion of the isolation region 122a. Here, the spacer 125a has a height substantially higher than that of the pattern structure 117.

Referring to FIG. 8, the hard mask layer pattern 115a is removed to expose the first conductive layer pattern 110a. When the hard mask layer pattern 115a is etched, the first conductive layer pattern 110a may be partially removed. Although the first conductive layer pattern 110a may be partially removed, the first conductive layer pattern 110a may still have the thickness of about 1,000 Å after the hard mask layer pattern 115a is removed if the first conductive layer pattern 110a has the initial thickness of about 1,200 Å.

After the hard mask layer pattern 115a is removed, a first gate electrode 130 including the first conductive layer pattern 110a and the spacer 125a is formed on the substrate 100.

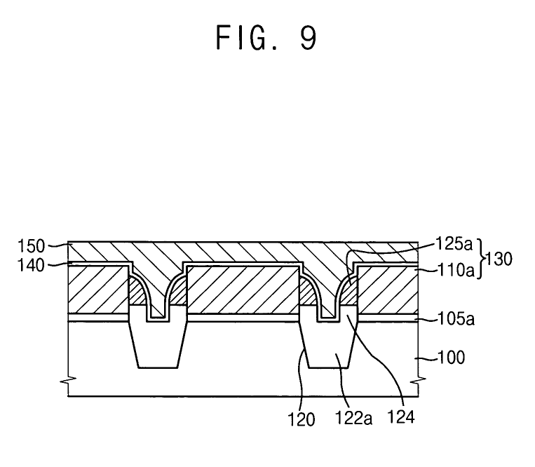

In some exemplary embodiments of the present invention, the first conductive layer pattern 110a has the single thin film polysilicon structure so that the first conductive layer pattern 110a may have a dense structure. In addition, because the spacer 125a is formed on a sidewall of the first conductive layer pattern 110a, an area of a cell region of the semiconductor device may be augmented and the active region of the substrate 100 may be sufficiently protected by the spacer 125a in the etching processes for forming the first gate electrode 130. As a result, the first gate electrode 130 having the first conductive layer pattern 110a and the spacer 125a may have good electrical characteristics. Furthermore, the isolation region 122a having the recess 124 may effectively reduce the electron interference between the first gate electrodes 130, and the recess 124 may also increase a surface area of the isolation region 122a. Thus, the semiconductor device may have a high coupling constant because a dielectric layer 140 (see FIG. 9) is formed on the isolation region 122a has increased surface area.

Referring to FIG. 9, a dielectric layer 140 is formed on the first gate electrode 130 and the isolation region 122a, that is, the dielectric layer 140 is formed on the first conductive layer pattern 110a, the spacer 125a and the isolation region 122a. The dielectric layer 140 may include an oxide-nitride-oxide film. Alternatively, the dielectric layer 140 may include a metal oxide film having a high dielectric constant, for example, hafnium oxide or titanium oxide. The metal oxide film may be formed using an atomic layer deposition (ALD) process.

A third conductive layer 150 is formed on the dielectric layer 140 to fill the recess 124 and the gap between the first gate electrodes 130. The third conductive layer 150 may be substantially identical to the first conductive layer 110 except for a thickness thereof. For example, the third conductive layer 150 may include a polysilicon film substantially identical to a polysilicon film used for the first conductive layer 110. Alternatively, the third conductive layer 150 may include a metal film or a metal nitride film identical to that used for the first conductive layer 110. The third conductive layer 150 may be formed from polysilicon using two operations substantially identical to those described above for forming the first conductive layer 110.

The dielectric layer 140 and the third conductive layer 150 are sequentially etched to form a dielectric layer pattern and a second gate electrode. When the third conductive layer 150 is partially etched, the second gate electrode includes a third conductive layer pattern, such as a polysilicon film pattern. As a result, the semiconductor device, such as a flash memory device, including the first gate electrode 130, the dielectric layer pattern and the second gate electrode is formed on the substrate 100. Here, the first gate electrode 130 and the second gate electrode correspond to the floating gate and a control gate, respectively.

According to some exemplary embodiments of the present invention, a tunnel oxide layer is formed before forming an isolation region so that a thinning of the tunnel oxide layer may be effectively prevented in successive processes for forming a semiconductor device. In addition, because a trench is formed self-aligned to a previously formed first gate electrode, a process margin of a process for forming the trench may be sufficiently ensured. Furthermore, the first gate electrode may be easily formed without generating a void therein and considering a gap-filling margin thereof because a conductive layer pattern of the gate electrode may have a single thin film structure.

According to further exemplary embodiments of the present invention, the first gate electrode includes a spacer so that an area of a cell region of a semiconductor device may be greater. The spacer may also effectively reduce damage to an active region in subsequent etching processes for forming the semiconductor device. Additionally, because the isolation region has a recess thereon, electron interferences generated between the first gate electrodes may be reduced and/or prevented, and a dielectric layer formed on the isolation region may have an increased surface area. As a result, the semiconductor device may have improved electrical characteristics.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A semiconductor device comprising:
an isolation region provided in a trench in a substrate and having a recess therein;
a tunnel oxide layer pattern on the substrate adjacent the isolation region;
a first gate electrode provided on the tunnel oxide layer pattern and extending onto a portion of the isolation region adjacent the recess;
a dielectric layer provided on the first gate electrode; and
a second gate electrode provided on the dielectric layer and extending into the recess in the isolation region.

2. The device of claim 1, wherein the first gate electrode comprises:
a conductive layer pattern provided on the tunnel oxide layer pattern; and
a conductive spacer provided on a sidewall of the first conductive layer pattern adjacent the recess in the isolation region.

3. The device of claim 2, wherein the tunnel oxide layer pattern has a thickness of about 10 Å to about 500 Å.

4. The device of claim 2, wherein the conductive layer pattern has a thickness of about 700Å to about 1,500 Å.

5. The device of claim 2, wherein the recess has a depth of about 200 Å to about 300 Å.

6. The device of claim 2:
wherein the tunnel oxide layer pattern has a thickness of about 10 Å to about 500 Å;
wherein the conductive layer pattern has a thickness of about 700 Å to about 1,500 Å; and
wherein the recess has a depth of about 200 Å to about 300 Å.

7. The device of claim 2, wherein each of the conductive layer, the conductive spacer and the second gate electrode comprise doped polysilicon.

8. The device of claim 2, wherein the dielectric layer comprises an oxide-nitride-oxide film or a metal oxide film.

9. The device of claim 1, wherein the dielectric layer conforms to the first gate electrode and to the recess in the isolation region.

10. A method of manufacturing a semiconductor device, the method comprising:
forming a tunnel oxide layer on a substrate;
forming a conductive layer on the tunnel oxide layer;
removing portions of the conductive layer, the tunnel oxide layer, and the substrate to form a pattern structure including a tunnel oxide layer pattern and a conductive layer pattern on the substrate and a trench in the substrate adjacent the pattern structure;
forming an isolation region in the trench;
forming a conductive spacer on a sidewall of the first conductive layer pattern and on the isolation region to form a first gate electrode including the conductive layer pattern and the conductive spacer;
forming a recess in the isolation region adjacent the spacer;
forming a dielectric layer on the first gate electrode; and
forming a second gate electrode on the dielectric layer and extending into the recess in the isolation region.

11. The method of claim 10, wherein forming a tunnel oxide layer comprises thermally oxidizing the substrate to produce a tunnel oxide layer having a thickness of about 10 Å to about 500 Å.

12. The method of claim 10, wherein forming a conductive layer comprises forming the conductive layer by a thermal decomposition process to produce a conductive layer having a thickness of about 700 Å to about 1,500 Å.

13. The method of claim 10, wherein each of the first gate electrode and the second gate electrode comprise doped polysilicon.

14. The method of claim 13, wherein each of the conductive layer, the spacer and the second gate electrode are formed using a thermal decomposition process followed by an impurity doping process.

15. The method of claim 14, wherein the thermal decomposition process is performed at a temperature of about 500° C. to about 650° C. and a pressure of about 25 Pa to about 150 Pa.

16. The method of claim 14, wherein the thermal decomposition process is performed using a pure silane gas or a silane gas diluted with nitrogen, wherein the diluted silane gas includes about 20 weight percent to about 30 weight percent of silane.

17. The method of claim 10:
wherein forming a conductive layer comprises forming a first conductive layer;
wherein removing portions of the conductive layer, the tunnel oxide layer, and the substrate to form a pattern structure including a tunnel oxide layer pattern and a conductive layer pattern on the substrate and a trench in the substrate adjacent the pattern structure is preceded by forming a hard mask layer on the first conductive layer;
wherein removing portions of the conductive layer, the tunnel oxide layer, and the substrate to form a pattern structure including a tunnel oxide layer pattern and a conductive layer pattern on the substrate and a trench in the substrate adjacent the pattern structure comprises removing portions of the hard mask layer, the conductive layer, the tunnel oxide layer and the substrate to form a pattern structure including a hard mask layer pattern on the tunnel oxide layer pattern and the conductive layer pattern;
wherein forming a conductive spacer comprises:
forming a second conductive layer on the pattern structure and the isolation region; and
etching with an etchant having an etching selectivity between the hard mask layer pattern and the second conductive layer to form the conductive spacer.

18. The method of claim 17, wherein forming a recess in the isolation region adjacent the spacer comprises etching with an etchant having an etching selectivity between the isolation region and the hard mask layer pattern.

19. The method of claim 10, wherein the recess has a depth of about 200 Åto about 300 Å.

20. The method of claim 10, wherein the dielectric layer comprises an oxide-nitride-oxide film or a metal oxide film.

21. The method of claim 10, wherein the dielectric layer conforms to the first gate electrode and to the recess in the isolation region

22. A method of manufacturing a semiconductor device, the method comprising:
forming a tunnel oxide layer on a substrate;
forming a polysilicon film on the tunnel oxide layer;
removing portions of the tunnel oxide layer and the polysilicon film to form a pattern structure including a tunnel oxide layer pattern and a polysilicon film pattern on the substrate;
forming a trench in the substrate adjacent the pattern structure;
forming an isolation region in the trench;
forming a polysilicon spacer on a sidewall of the first polysilicon layer pattern to form a first polysilicon gate electrode including the first polysilicon layer pattern and the polysilicon spacer;
forming a recess in the isolation region adjacent the polysilicon spacer;
forming a dielectric layer on the first polysilicon gate electrode and the isolation region; and
forming a second polysilicon gate electrode on the dielectric layer and extending into the recess.

23. The method of claim 22, wherein forming a tunnel oxide layer comprises forming the tunnel oxide layer by a thermal oxidation process to a thickness of about 10 Å to about 500 Å.

24. The method of claim 22, wherein the first polysilicon film has a thickness of about 700 Å to about 1,500 Å.

25. The method of claim 22, wherein each of the first polysilicon film, the second polysilicon film and the third polysilicon film are formed using a thermal decomposition process followed by an impurity doping process.

26. The method of claim 25, wherein the thermal decomposition process is carried out a temperature of about 500° C. to about 650° C. and a pressure of about 25 Pa to about 150 Pa.

27. The method of claim 25, wherein the thermal decomposition process is performed using a pure silane gas or a silane gas diluted with nitrogen, wherein the diluted silane gas includes about 20 weight percent to about 30 weight percent of silane.

28. The method of claim 25, wherein the impurity doping process comprises a diffusion process, an ion implantation process or an in-situ doping process.

29. The method of claim 22:
wherein forming a polysilicon film comprises forming a first polysilicon film;
wherein removing portions of the tunnel oxide layer and the polysilicon film to form a pattern structure including a tunnel oxide layer pattern and a polysilicon film pattern on the substrate is preceded by forming a hard mask layer on the first polysilicon film;
wherein removing portions of the tunnel oxide layer and the polysilicon film to form a pattern structure including a tunnel oxide layer pattern and a polysilicon film pattern on the substrate comprises removing portions of the hard mask layer, the tunnel oxide layer and the polysilicon film to form a pattern structure including a hard mask layer pattern on the tunnel oxide layer pattern and the polysilicon film pattern; and
wherein forming a polysilicon spacer on a sidewall of the first polysilicon layer pattern to form a first polysilicon gate electrode including the first polysilicon layer pattern and the polysilicon spacer comprises:
forming a second polysilicon film on the pattern structure and the isolation region; and
etching the second polysilicon film by using an etching solution that has an etching selectivity between the second polysilicon film and the hard mask layer pattern to form the polysilicon spacer.

30. The method of claim 29, wherein forming a recess in the isolation region adjacent the polysilicon spacer comprises etching the isolation region using an etching solution that has an etching selectivity between the isolation region and the hard mask layer pattern.

31. The method of claim 22, wherein the recess has a depth of about 200 Å to about 300 Å.

32. The method of claim 22, wherein the dielectric layer comprises an oxide-nitride-oxide film or a metal oxide film.
